(19) United States
(12) Patent Application Publication
(10) Pub. No.: US 2009/0173715 A1
(43) Pub. Date: Jul. 9, 2009

(54) LIGHT SOURCE DEVICE, SUBSTRATE TREATING DEVICE, AND SUBSTRATE TREATING METHOD

(75) Inventors: Yasuhiro Oshima, Austin, TX (US); Nobuaki Takahashi, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/162,617

(22) PCT Filed: Jan. 29, 2007
(86) PCT No.: PCT/JP2007/051406

§ 371 Date: Jul. 30, 2008

(30) Foreign Application Priority Data
Jan. 31, 2006 (JP) 2006-023283

(51) Int. Cl. H01L 21/306; C23C 14/28

(52) U.S. Cl. 216/23; 118/723 AN; 156/345.36; 427/595

(57) ABSTRACT

A light source device is formed by a plasma formation chamber including a plasma formation region where plasma is formed by electrodeless discharge to generate light and an optical window defining the lower end of the plasma region in the plasma formation chamber and transmitting the light. A microwave transmitting window is formed in the plasma chamber for introducing microwaves for generating the plasma. Furthermore, outside of the microwave transmitting window, a microwave antenna is connected to the microwave window for introducing the microwaves.

### FIELD OF ART

The present invention generally relates to fabrication of semiconductor devices, more particularly to a light source device which is used in a fabrication process of semiconductor devices, and to a substrate treatment device including the light source device.

### BACKGROUND ART

Ultraviolet light source are widely used for the fabrication process of semiconductor devices including liquid crystal display devices, where the ultraviolet light is used to improve the characteristics of films formed on a substrate or to generate radicals including oxygen radicals and halogen radicals in the fabrication process.

It is known that a technique for oxidizing the surface of a silicon substrate with oxygen radicals formed by exciting oxygen gas using an ultraviolet light source. Further, it is known that an etching technique uses halogen radicals that are generated by ultraviolet light excitation.

### DISCLOSURE OF THE INVENTION

### Problems to be Solved by the Invention

In such ultraviolet light source, in general, high-pressure mercury lamp, low-pressure mercury lamp, and excimer lamp are widely used. Such lamp is a tubular light source or a spotted light source. In order to generate uniform ultraviolet light over a large area it is required to place a plurality of the light sources or to rotate a substrate being treated by using a complex mechanism.

Moreover, such light sources have a short lifetime of operation which requires frequent replacement of the light sources. Especially for a substrate treating device with a plurality of light sources for treating a large diameter substrate, the cost of such light sources is a main factor raising the production cost of semiconductor devices.

The present invention provides an ultraviolet light source device enabling emission of uniform ultraviolet light over a large area, and a substrate treating device having such ultraviolet light source device.

Patent Reference 1: Japanese Patent Application Publication H07-106299

### Means to Solve the Problems

One aspect according to the present invention provides a light source device comprising: a plasma formation chamber having a plasma formation region for forming plasma in said plasma formation region by electrodeless discharge to generate light emission;

an optical window defining a lower end of said plasma formation region in said plasma formation chamber and transmitting said light emission;

a microwave transmitting window introducing a microwave into said plasma formation chamber to form said plasma; and

a microwave antenna connected to said microwave transmitting window outside of said microwave transmitting window for introducing said microwave.

Further, another aspect of the present invention provides a substrate treating device comprising:

a treating vessel that defines a processing space, and includes a substrate holding stage for holding a substrate to be treated in said processing space; and

a light source device facing said substrate to be treated on said substrate holding stage at an upper part of said treating vessel,

wherein said light source device comprises:

a plasma formation chamber having a plasma formation region for forming plasma in said plasma formation region by electrodeless discharge to generate light emission;

an optical window defining the lower end of said plasma formation region in said plasma formation chamber and transmitting said light emission;

a microwave transmitting window for introducing a microwave into said plasma formation chamber to form said plasma;

a microwave antenna connected to said microwave transmitting window outside of said microwave transmitting window for introducing said microwave;

a first gas inlet port for introducing a first gas into said plasma formation region;

a second gas inlet port for introducing a second gas into said processing space;

an evacuation port for evacuating said processing space; and

an opening part in said optical window for connecting said plasma formation chamber and said processing space.

Further, another aspect of the present invention provides a substrate treating device comprising:

a treating vessel that defines a processing space, and includes a substrate holding stage for holding a substrate to be treated in said processing space;

a light source device facing said substrate to be treated on said substrate holding stage at the upper part of said treating vessel;

wherein said light source device comprises:

a plasma formation chamber having a plasma formation region for forming plasma in said plasma formation region by electrodeless discharge to generate light emission;

an optical window defining the lower end of said plasma formation region in said plasma formation chamber and transmitting said light emission;

a microwave transmitting window for introducing a microwave into said plasma formation chamber to form said plasma;

a microwave antenna connected to said microwave transmitting window outside of said microwave transmitting window for introducing said microwave;

a first gas inlet port for introducing a first gas into said plasma formation chamber;

a second gas inlet port for introducing a second gas into said processing space;

a first outlet port for evacuating said plasma formation chamber; and

a second outlet port for evacuating said processing space.

Further, another aspect of the present invention provides a method of a treating substrate by utilizing a substrate treating device, wherein said device comprises:

a treating vessel that defines a processing space and includes a substrate holding stage for holding a substrate to be treated in said processing space; and

a light source device facing said substrate to be treated on said substrate holding stage at the upper part of said treating vessel,

wherein said light source device comprises:

a plasma formation chamber having a plasma formation region for forming plasma in said plasma formation region by electrodeless discharge to generate light emission;

an optical window defining the lower end of said plasma formation region in said plasma formation chamber and transmitting said light emission;

a microwave transmitting window for introducing a microwave into said plasma formation chamber to form said plasma;

a microwave antenna being connected to said microwave transmitting window outside of said microwave transmitting window for introducing said microwave;

a first gas inlet port for introducing a first gas into said plasma formation chamber;

a second gas inlet port for introducing a second gas into said processing space;

a first outlet port for evacuating said plasma formation chamber space;

a second outlet port for evacuating said processing space;

a first outlet valve that is provided for said first outlet port;

a second outlet valve that is provided for said second outlet port;

a communicating path to connect said plasma formation chamber and said processing space; and

a third valve that is provided in said communicating path,

said method comprising at least one of

a first step of closing said third valve and opening said first and said second valves to form plasma in said plasma formation region to expose plasma light emission to said substrate to be treated; and

a second step of treating a surface of said substrate to be treated with radicals caused by said plasma in said processing space,

wherein said second and third valves are opened and said first valve is closed.

### EFFECT OF THE INVENTION

According to the present invention, a large diameter light source with a long lifetime and a uniform light emission over a large area is obtained, wherein the light emission method comprises: forming plasma in a plasma formation region by electrodeless discharge with a microwave antenna, with a microwave transmitting window facing an optical window, and irradiating light emission caused by the plasma through the optical window. Using such a light source allows performing high quality substrate treatment at low cost. Such a light source can be integrated with a substrate treatment device that uses plasma.

### BRIEF DESCRIPTION OF THE DRAWINGS

FIG. 1 is a diagram showing the construction of a substrate treating device according to a first embodiment of the present invention;

FIG. 2 is a different diagram showing a substrate treating device according to a first embodiment of the present invention;

FIG. 3 is a spectrum of Xe radiated from the light source in the diagram of FIG. 1;

FIG. 4 is a diagram showing the construction of a substrate treating device according to a second embodiment of the present invention;

FIG. 5 is a diagram showing the construction of a light source device according to the second embodiment of the present invention;

FIG. 6 is a diagram showing the construction of a different type of a light source device according to the second embodiment of the present invention;

FIG. 7 is a diagram showing the construction of a substrate treating device according to a third embodiment of the present invention;

FIG. 8A is a diagram showing an operating mode of the substrate treating device in the diagram of FIG. 6;

FIG. 8B is a diagram showing a different operating mode of the substrate treating device in the diagram of FIG. 6.

### BEST MODE FOR IMPLEMENTING THE INVENTION

### First Embodiment

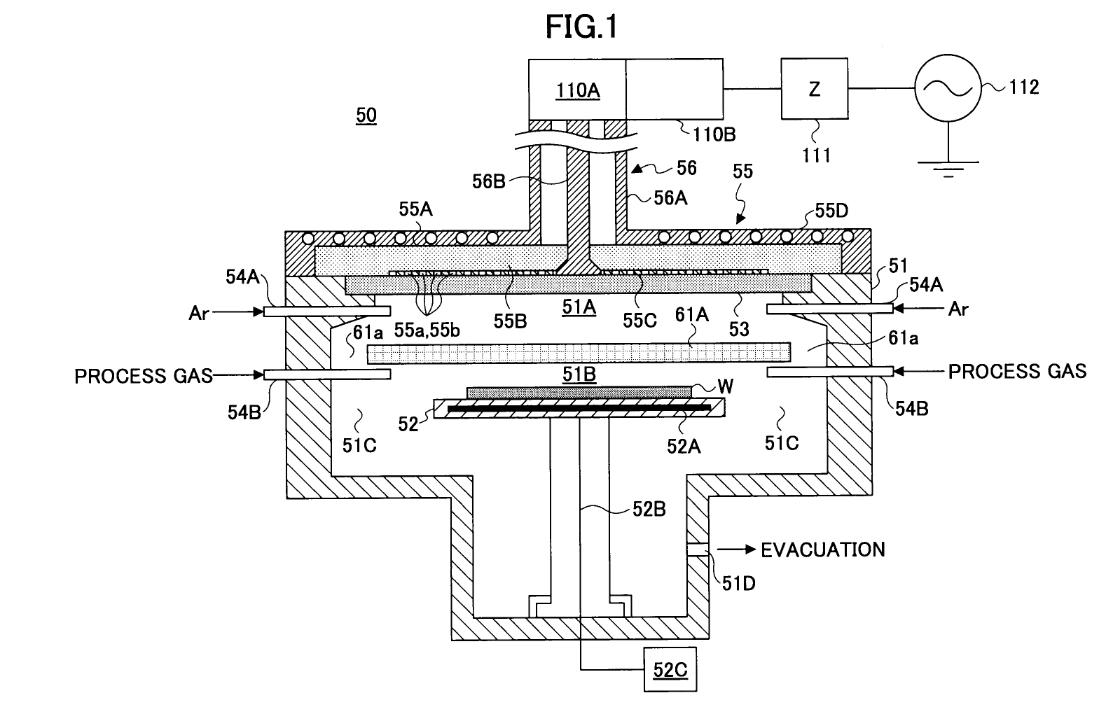

FIG. 1 shows the construction of a substrate treating device 50 having a microwave plasma light source device, according to a first embodiment of the present invention.

Referring to FIG. 1, the substrate treating device 50 includes a treating vessel 51, and a substrate holding stage 52 for holding a substrate W to be treated in the vessel 51. The treating vessel 51 is evacuated with an evacuation port 51D through space 51C surrounding the substrate holding stage 52.

The substrate holding stage 52 is provided with a heater 52A, and the heater 52A is operated by a power source 52C through an operation line 52B.

In the treating vessel 51, an optical window 61A is comprised of a dielectric material such as quartz glass, AlN, Al₂O₃, or Y₂O₃ for transmitting ultraviolet light, and faces the substrate W to be treated. The space in the treating vessel is divided by the optical window 61A into a plasma formation space 51A, the upper part and a processing space 51B, the lower part. In the present embodiment shown in this figure, the plasma formation space 51A and the processing space 51B are connected through an opening 61a of the optical window 61A which the opening 61a is provided outside of the substrate W to be treated.

The opening 61a is formed by a plurality of holes or slits. The opening 61a may have any shape, provided that the opening is communicatable with the plasma formation space and the processing space.

At the top of the treating vessel 51, an opening is formed facing the optical window 61A. The opening is airtightly closed with a top plate 53 that is made of a dielectric material such as quartz glass, AlN, Al₂O₃, or Y₂O₃. Further, positioned underneath the top plate 53 and over the optical window 61A, there is a gas introducing part 54 with a gas inlet and a gas ring having a large number of nozzle openings that communicate with the gas inlet. Through gas inlet ports 54A, an inert gas such as Ar, Kr, Xe, He, or Ne is introduced into the plasma formation space 51A.

Further, for the treating vessel 51, another gas ring 54B is provided below the optical window 61A, and gas such as oxygen gas, nitrogen gas, N₂O gas, NO gas, NO₂ gas, hydrocarbon gas, fluorocarbon gas, or inert gas is introduced into the processing space 51B for the purpose of substrate treatment of the substrate W to be treated.

The top plate 53 functions as a microwave transmitting window. An antenna part 55 including a radial line slot antenna 55C is provided at the upper part of the top plate 53. A horn antenna can be used instead of the antenna.

In the illustrated example, a plane antenna is comprised of the radial line slot antenna 55C. Thus the antenna part 55 includes a flat conductor part 55A, a retardation plate 55B, and a radial line slot antenna 55C. The retardation plate 55B covers the radial line slot antenna 55C, and the retardation plate 55B is made of a dielectric material such as quartz or alumina.

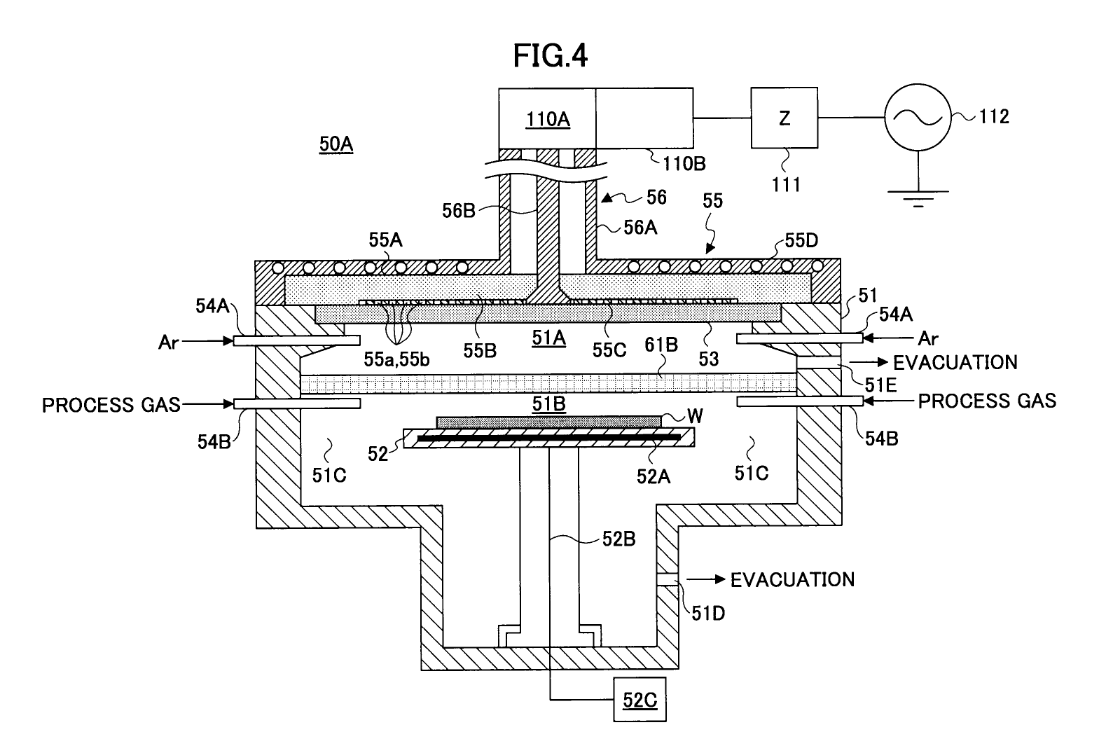

The radial line slot antenna 55C is provided with a large number of slots 55a and 55b, which will be explained with reference to FIG. 4. The antenna part 55 is connected to a coaxial waveguide 56 having an outer waveguide 56A and an inner waveguide 56B. The outer waveguide 56A is connected to the conductor part 55A of the antenna part 55, and the inner waveguide 56B penetrating the retardation plate 55B is connected to the radial line slot antenna 55C.

The inner waveguide 56B is connected to a rectangular cross-sectional waveguide 110B via a mode conversion part 110A. The rectangular cross-sectional waveguide 110B is connected to a microwave source 112 via an impedance matcher 111. Thereby, microwaves generated with the microwave source 112 are supplied to the antenna part 55 via the rectangular cross-sectional waveguide 110B and the coaxial waveguide 56.

In the construction of FIG. 1, a cooling unit 55D is provided on the conductor part 55A.

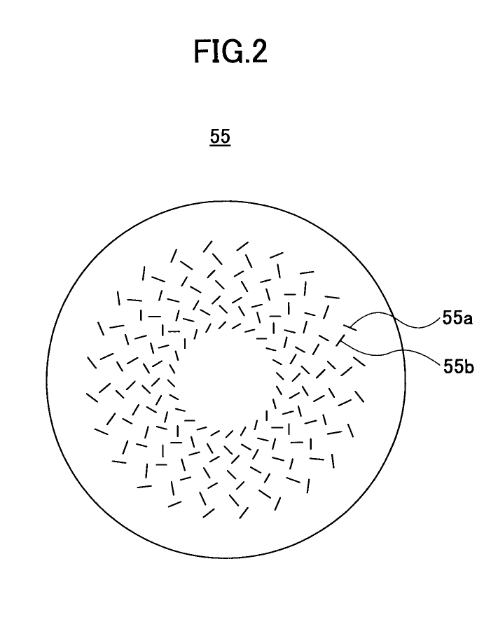

FIG. 2 shows the construction of the radial line slot antenna 55C in detail. It is noted that FIG. 2 is a plan view of the radial line slot antenna 55C.

Referring to FIG. 2, it is shown that the radial line slot antenna 55C includes a large number of slots 55a and 55b, which those slots are formed in a radial pattern and neighboring slots 55a and 55b are arranged perpendicular to each other. The slots 55a and 55b may be arranged either in a spiral pattern or a linear pattern.

When microwaves are supplied to the radial line slot antenna 55C from the coaxial waveguide 56, the microwaves propagate in the radial line slot antenna 55C while spreading radially, wavelengths are shortened by the retardation plate 55B. Thereby, the microwaves are emitted from the slots 55a and 55b as circularly polarized microwaves, and are generally perpendicular to the radial line slot antenna 55C.

In operation, the plasma formation space 51A and the processing space 51B in the treating vessel 51 are maintained at a predetermined pressure by evacuating through the evacuation port 51C, and an inert gas such as Ar, Kr, Xe, or Ne, is introduced into the plasma formation space 51A from the gas port 54A.

Further, microwaves having a frequency of 1˜20 GHz such as 2.45 GHz are introduced into the processing space 51A from the microwave source 112 through the antenna part 55. Consequently, high density plasma with a density of 10¹¹-10¹³/cm³ is excited at the surface of the substrate W to be treated. Plasma excited by such microwaves introduced via the antenna part 55 provide a feature of low electron temperature of 0.7-2 eV or less.

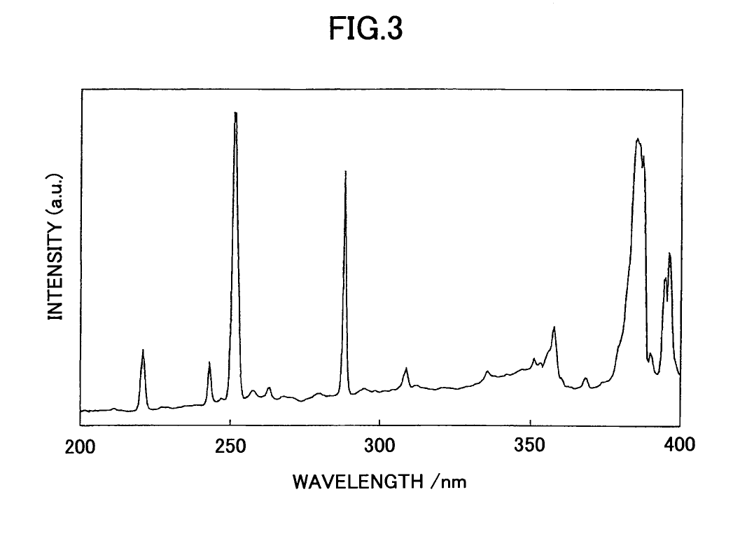

As a result of such plasma excitation, ultraviolet light is formed in the plasma formation space 51A, having Xe continuous spectra as shown in FIG. 3. Ultraviolet light with wavelengths of 10-400 nm is preferable, and a wavelength longer than 200 nm is more preferable for use of a quartz window. Such light emission intensity allows exciting a treating gas and performing substrate treatment. As the emission intensity varies according to the species of gas being excited, one may choose a gas being excited for suitable and efficient light emission. Thereby, for the substrate treating device 50 of FIG. 1 and FIG. 2, it becomes possible for the substrate treatment in the processing space 51B to be performed by using the plasma light emission as a light source, in which the plasma light emission is caused by electrodeless discharge in the plasma formation space 51A. In this case, the upper portion from the optical window 61A constitutes a microwave plasma light source device.

For the construction of FIG. 1, as the plasma formation space 51A communicates with the processing space 51B via the opening 61a, the plasma formation space 51A is evacuated with the processing space at the same time.

According to the construction of FIG. 1 and FIG. 2, plasma is formed uniformly by a large diameter microwave antenna, and the plasma generates ultraviolet light. Using the ultraviolet light enables using it as a single light source for uniform light irradiation onto an object to be treated having a large area. There is no need to construct a large number of light sources with short lifetime operation, or to rotate the object to be treated. Consequently, it allows sufficiently reducing the cost of substrate treatment for treatment such as oxidation treatment or etching treatment that uses ultraviolet light treatment or oxygen radicals.

### Second Embodiment

FIG. 4 shows a construction of the substrate treating device 50A having an electrodeless discharge light source device according to a second embodiment of the present invention. In the figure, an explanation is left out for any corresponding part that has been explained above. Instead, an identical reference symbol is used for it.

Referring to FIG. 4, in this embodiment, a quartz optical window 61B without a communicating portion for communication between the plasma formation space 51A and the processing space 51B is provided to separate the two spaces instead of the optical window 61A. Further, an evacuation port 51E is formed in the treating vessel 51 for evacuating the plasma formation region 51A.

Thus, in the construction of FIG. 4, the plasma formation region 51A is independent of the processing space 51B, and a light source is formed above the optical window 61B, being independent from the substrate treating device that is below the optical window 61B. Utraviolet light is generated by plasma that is formed by introducing plasma gas such as inert gas into the plasma treating device 50A through a gas ring 54A.

In the present case, plasma is formed in the plasma formation region 51A, and the formed plasma generates ultraviolet light. A process gas is supplied through the gas inlet port 54B into the processing space 51B, the process gas is excited by the ultraviolet light, and active radicals of the process gas are formed. Then, the substrate W to be treated is treated by the active radicals.

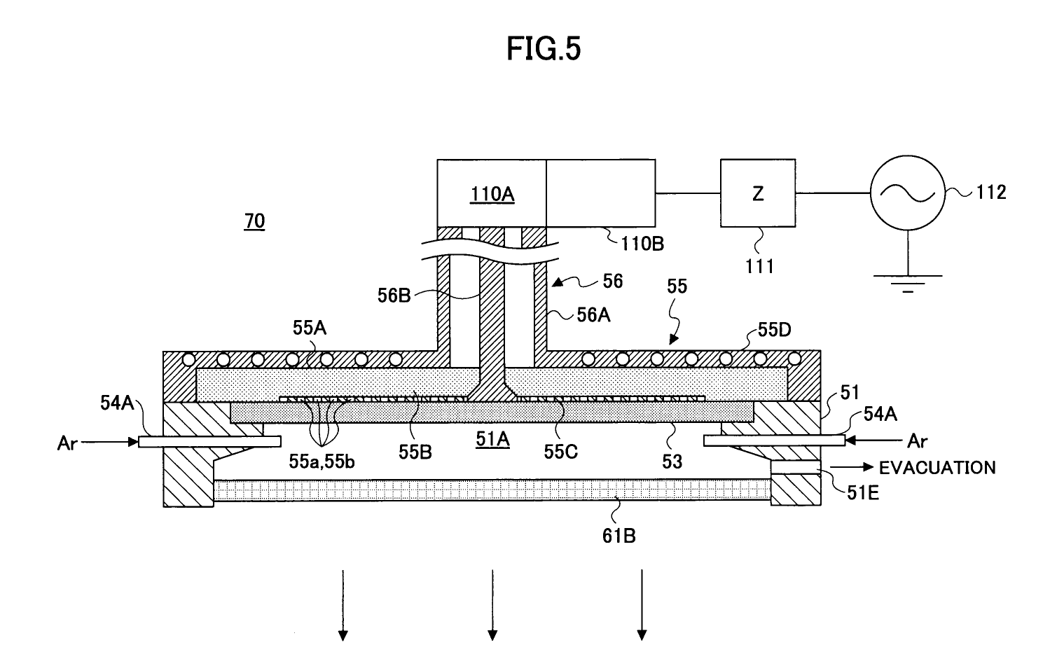

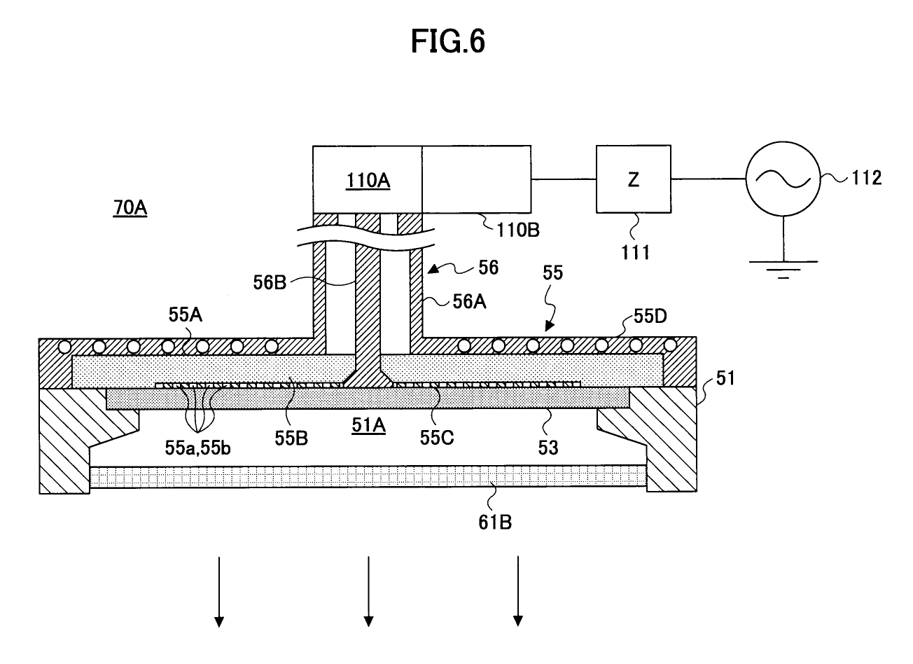

Further, for the construction of FIG. 4, only the light source device may be separated to construct an independent light source device 70, as shown in FIG. 5. Further, as shown in FIG. 6, by omitting the gas inlet port 54A and the evacuation port 51E from the light source device 70, a light source 70A may be constructed by supplying inert gas such as Ar, Kr, Xe, Ne, or He in the plasma formation region 51A.

### Third Embodiment

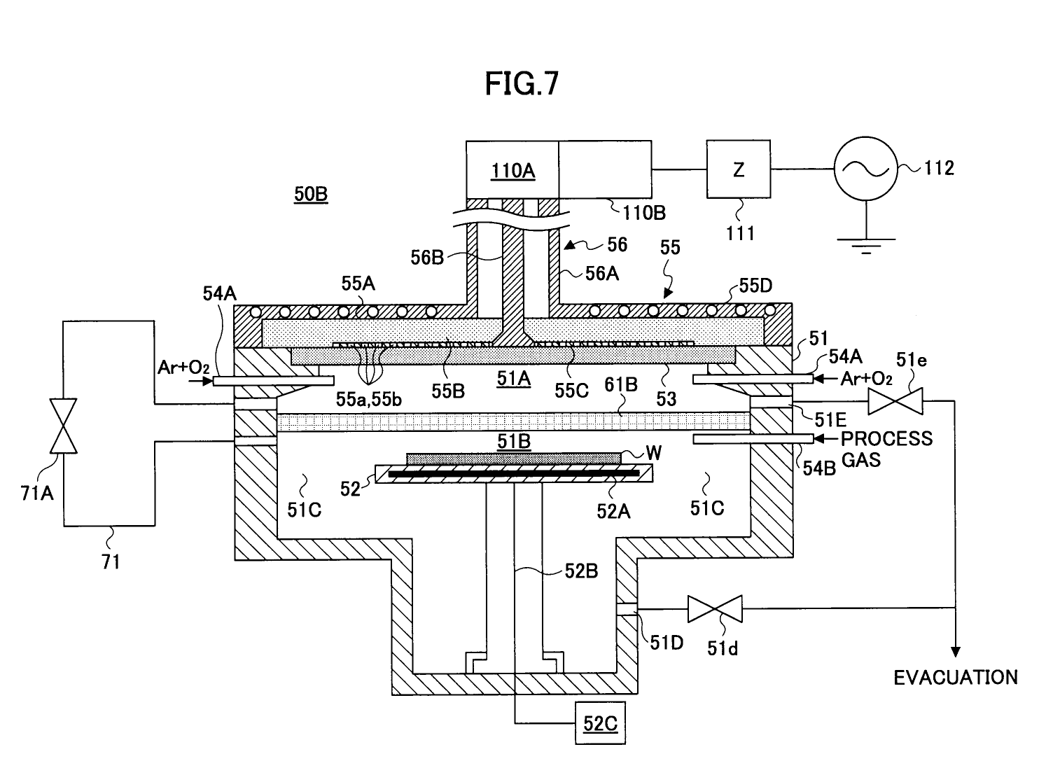

FIG. 7 shows a construction of a substrate treating device 50B according to a third embodiment of the present invention. In the figure, any part that has been explained previously above has an identical reference symbol, and the explanation for that part is omitted.

Referring to FIG. 7, a substrate treating device SOB has a similar construction to the substrate treating device 50A, wherein a line 71 is provided outside of a treating vessel 51 to connect the plasma formation space 51A and the processing space 51B, and the line 71 includes a valve 71A. Additionally, in the construction of the figure, the evacuation port 51D is evacuated through a valve 51d, and an evacuation port 51E is evacuated through a valve 51e. The evacuation of the plasma formation space 51A and the processing space 51B may be performed individually.

The valve 71A is opened when radicals generated in the plasma formation space 51A are to be introduced into the processing space 51B.

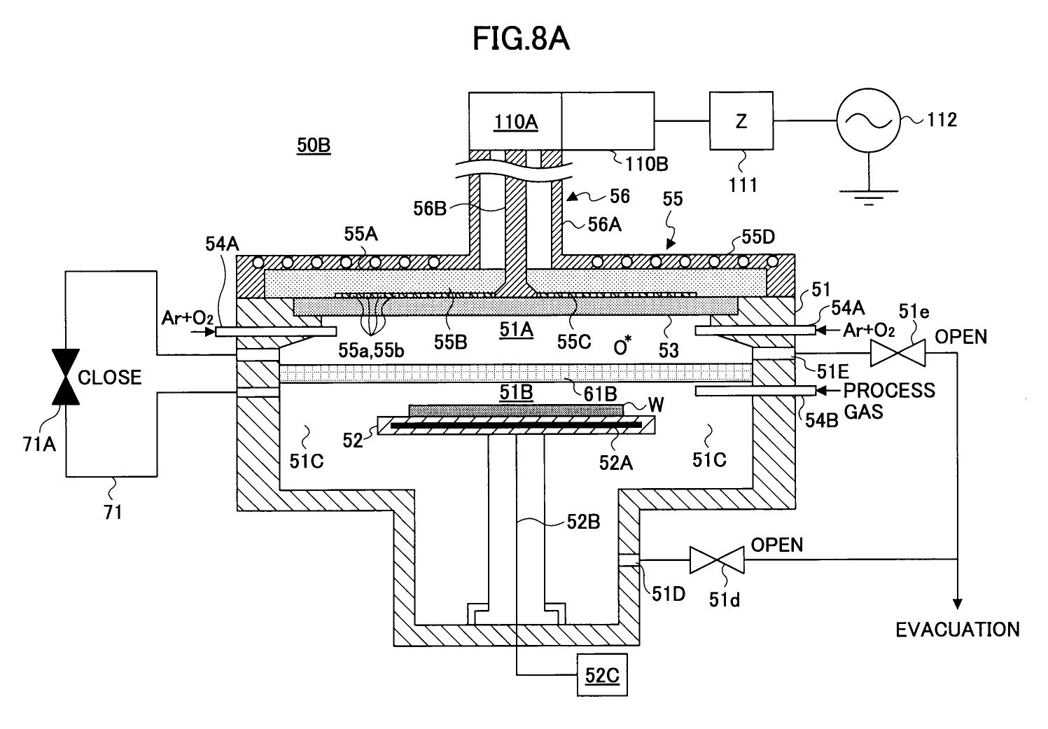

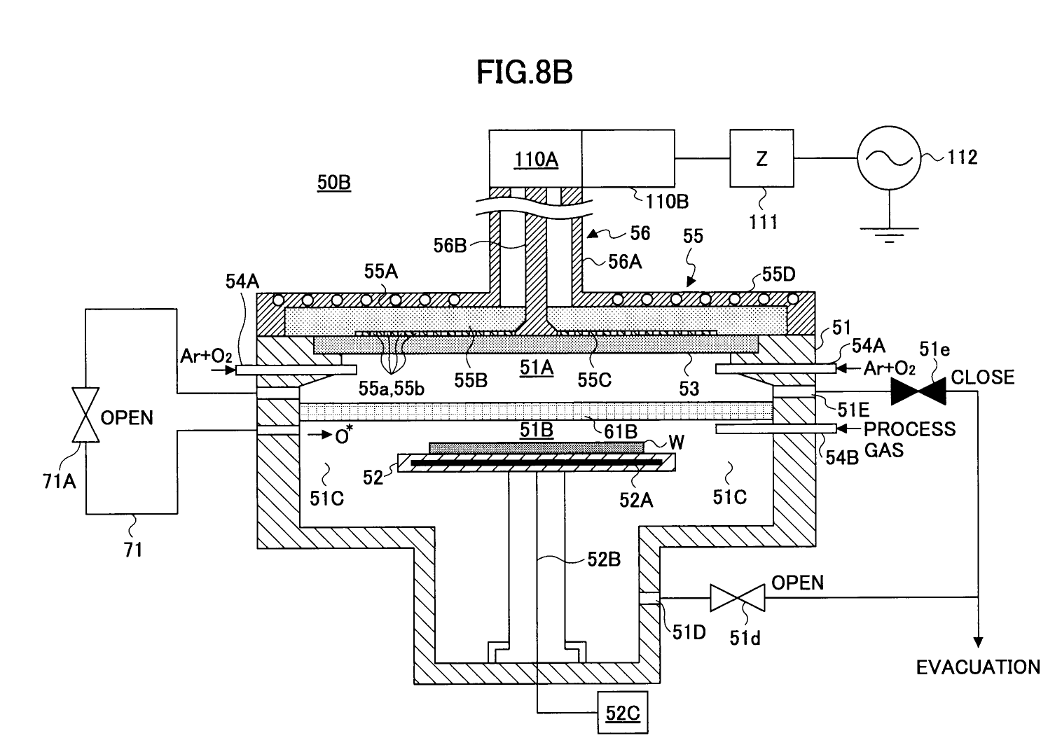

FIG. 8A and FIG. 8B show two operating modes of the substrate treating device 50B shown in FIG. 7.

In the operation mode of FIG. 8A, the valve 71A is closed, and the valves 51d and 51e are opened. Thereby, a light source part including the optical window 61B and plasma formation space 51A above the optical window 61B is operated separately from a substrate treating part below the optical window 61B. The light generated by the plasma formed in the plasma formation space is irradiated onto a substrate W to be treated on the substrate holding stage 52.

On the other hand, in the operating mode of FIG. 8B, the valve 71A is opened and the valve 51e is closed.

Consequently, when inert gas such as Ar gas is accompanied with oxygen gas or nitrogen gas and introduced to the plasma formation space 51A, oxygen radicals or nitrogen radicals formed in the plasma formation space 51A flow into the processing space 51B via the line 71 as a result of the evacuating effect between the evacuation port 51D and the valve 51d. Thereby, oxygen radical treatment is carried out at the surface of the substrate W to be treated. The present embodiment may be used for cleaning organic materials (e.g. hydrocarbons, C, and H) on the inside of the treating vessel 51, by using oxygen or hydrogen that is activated by irradiating ultraviolet light.

The operating modes of FIGS. 8A and 8B are independent of each other, and it is possible to use the modes separately. Further, the operating mode of FIG. 8A may be used after the operating mode of FIG. 7B, and the operating mode of FIG. 8B may be used after the operating mode of FIG. 7A.

Further, while the present invention has been explained with regard to preferred embodiments, the present invention is not limited to a particular embodiment but various variations and modifications may be made within the subject matter recited in claims.

As the present invention provides low damage treatment, this may be applied to curing of Low-K (low dielectric constant) films or UV light radiation cleaning.

The present invention claims priority to Japanese Patent Application No. 2006-02328 filed on Jan. 31, 2006, the entire contents of which are hereby incorporated by reference.

According to the present invention, a uniform light emission over a large area is achieved, and a large diameter light source with a long lifetime can be obtained. The present invention comprises:
a microwave transmitting window facing an optical window;
plasma formation by electrodeless discharge in a plasma formation region using a microwave antenna;
and irradiation of light generated by the plasma through the optical window.

It becomes possible that high quality substrate treatment is performed at low cost utilizing such a light source. This light source can be integrated with a substrate treating device.

1. A light source device comprising:
a plasma formation chamber having a plasma formation region for forming plasma in said plasma formation region by electrodeless discharge to generate light emission;
an optical window defining a lower end of said plasma formation region in said plasma formation chamber and transmitting said light emission;
a microwave transmitting window introducing a microwave into said plasma formation chamber to form said plasma; and
a microwave antenna connected to said microwave transmitting window outside of said microwave transmitting window for introducing said microwave.

2. The light source device according to claim 1, wherein said microwave antenna includes a radial line slot antenna having a plurality of slots.

3. The light source device according to claim 1, wherein said plasma formation chamber includes an outlet port to evacuate said plasma formation chamber and a gas inlet port to introduce gas into said plasma formation region.

4. The light source device according to claim 3, wherein a communicating path is formed in said plasma formation chamber to connect between said plasma formation region and a lower region that is lower than said optical window, and said outlet port is formed in said lower region.

5. The light source device according to claim 3, wherein an outlet port is formed in said plasma formation region of said plasma formation chamber.

6. A substrate treating device comprising:
a treating vessel that defines a processing space, and includes a substrate holding stage for holding a substrate to be treated in said processing space; and
a light source device facing said substrate to be treated on said substrate holding stage at an upper part of said treating vessel,
wherein said light source device comprises:
a plasma formation chamber having a plasma formation region for forming plasma in said plasma formation region by electrodeless discharge to generate light emission;
an optical window defining the lower end of said plasma formation region in said plasma formation chamber and transmitting said light emission;
a microwave transmitting window for introducing a microwave into said plasma formation chamber to form said plasma;
a microwave antenna connected to said microwave transmitting window outside of said microwave transmitting window for introducing said microwave;
a first gas inlet port for introducing a first gas into said plasma formation region;
a second gas inlet port for introducing a second gas into said processing space;
an evacuation port for evacuating said processing space; and
an opening part in part of said optical window for connecting said plasma formation chamber and said processing space.

7. The substrate treating device according to claim 6, wherein said opening part is formed to correspond to the outer part of said substrate to be treated on said substrate holding stage.

8. A substrate treating device comprising:
a treating vessel that defines a processing space, and includes a substrate holding stage for holding a substrate to be treated in said processing space;
a light source device facing said substrate to be treated on said substrate holding stage at the upper part of said treating vessel;
wherein said light source device comprises:
a plasma formation chamber having a plasma formation region for forming plasma in said plasma formation region by electrodeless discharge to generate light emission;
an optical window defining the lower end of said plasma formation region in said plasma formation chamber and transmitting said light emission;
a microwave transmitting window for introducing a microwave into said plasma formation chamber to form said plasma;
a microwave antenna connected to said microwave transmitting window outside of said microwave transmitting window for introducing said microwave;
a first gas inlet port for introducing a first gas into said plasma formation chamber;
a second gas inlet port for introducing a second gas into said processing space;
a first outlet port for evacuating said plasma formation chamber; and
a second outlet port for evacuating said processing space.

9. The substrate treating device according to claim 8, further comprising:
a communicating path to be provided outside of said treating vessel for connecting said plasma formation chamber and said process space; and
a valve to be provided in said communicating path.

10. The substrate treating device according to claim 6, wherein said microwave antenna includes a radial line slot antenna having a plurality of slots.

11. The substrate treating device according to claim 6, wherein a first outlet valve is provided for said first outlet port, and a second outlet valve is provided for said second outlet port.

12. A method of treating a substrate utilizing a substrate treating device that comprises:
a treating vessel that defines a processing space, and includes a substrate holding stage for holding a substrate to be treated in said processing space; and
a light source device facing said substrate to be treated on said substrate holding stage at the upper part of said treating vessel,
wherein said light source device comprises:
a plasma formation chamber having a plasma formation region for forming plasma in said plasma formation region by electrodeless discharge to generate light emission;
an optical window defining the lower end of said plasma formation region in said plasma formation chamber and transmitting said light emission;
a microwave transmitting window for introducing a microwave into said plasma formation chamber to form said plasma;
a microwave antenna connected to said microwave transmitting window outside of said microwave transmitting window for introducing said microwave;
a first gas inlet port for introducing a first gas into said plasma formation chamber;
a second gas inlet port for introducing a second gas into said processing space;
a first outlet port for evacuating said plasma formation chamber space;
a second outlet port for evacuating said processing space;
a first outlet valve that is provided for said first outlet port;
a second outlet valve that is provided for said second outlet port;
a communicating path to connect said plasma formation chamber and said processing space;
a third valve to be provided in said communicating path;
said method comprising at least one of
a first step of closing said third valve and opening said first and said second valves to form plasma in said plasma formation region to expose said substrate to be treated by to plasma light emission; and
a second step of treating a surface of said substrate to be treated with radicals caused by said plasma in said processing space,
wherein said second and third valves are opened and said first valve is closed.

13. The substrate treating method according to claim 12, wherein the first step and the second step are performed in either a first sequence or a second sequence,
the first sequence being defined by said second step following said first step;
the second sequence being defined by said first step following said second step.
